(19) United States
(12) Patent Application Publication
(10) Pub. No.: US 2026/0169595 A1
(43) Pub. Date: Jun. 18, 2026

(54) HAPTIC FEEDBACK PANEL AND DRIVING METHOD THEREOF, AND HAPTIC FEEDBACK APPARATUS

(71) Applicant: BOE Technology Group Co., Ltd., Beijing (CN)

(72) Inventors: Hui HUA, Beijing (CN); Yuju CHEN, Beijing (CN); Yingzi WANG, Beijing (CN)

(21) Appl. No.: 18/711,845

(22) PCT Filed: Jan. 17, 2023
(86) PCT No.: PCT/CN2023/072637

§ 371 Date: May 20, 2024

(51) Int. Cl. G06F 3/043; H10N 30/87

(52) U.S. Cl. CPC G06F 3/043; H10N 30/872

(57) ABSTRACT

Embodiments of the present disclosure provide a haptic feedback panel and a driving method thereof, and a haptic feedback apparatus. The haptic feedback panel includes: a touch substrate; at least one first piezoelectric device on the touch substrate; where the first piezoelectric device includes a single first piezoelectric layer, and the first piezoelectric device is configured to detect pressure pressed onto a surface of the touch substrate; and at least one second piezoelectric device on the touch substrate; where the second piezoelectric device includes at least three electrode layers that are stacked, and a second piezoelectric layer between every two adjacent electrode layers; and the second piezoelectric device is configured to vibrate under an action of an alternating electric field and to drive the touch substrate to resonate.

### CROSS REFERENCE TO RELATED APPLICATIONS

The present disclosure is a US National Stage of International Application No. PCT/CN2023/072637, filed on Jan. 17, 2023, the entire contents of which are incorporated herein by reference.

### TECHNICAL FIELD

The present disclosure relates to the field of haptic feedback technology, and in particular, relates to a haptic feedback panel and a driving method thereof, and a haptic feedback apparatus.

### BACKGROUND

With the development of display technology, a touch screen has been more and more widely used, and gradually become one of the most convenient human-computer interaction devices. In recent years, in order to further improve the use experience of human-computer interaction, the haptic feedback technology has emerged and received more and more attention and research.

### SUMMARY

Embodiments of the present disclosure provide a haptic feedback panel and a driving method thereof, and a haptic feedback apparatus. The specific solutions are as follows.

An embodiment of the present disclosure provides a haptic feedback panel, including: a touch substrate; at least one first piezoelectric device on the touch substrate; wherein the first piezoelectric device includes a single first piezoelectric layer, and the first piezoelectric device is configured to detect pressure pressed onto a surface of the touch substrate; and at least one second piezoelectric device on the touch substrate; wherein the second piezoelectric device includes at least three electrode layers that are stacked, and a second piezoelectric layer between every two adjacent electrode layers; and the second piezoelectric device is configured to vibrate under an action of an alternating electric field and to drive the touch substrate to resonate.

In a possible implementation, in the above haptic feedback panel provided by an embodiment of the present disclosure, the first piezoelectric device and the second piezoelectric device are both disposed on a non-touch surface of the touch substrate; and an orthographic projection of the first piezoelectric device on the touch substrate and an orthographic projection of the second piezoelectric device on the touch substrate do not overlap.

In a possible implementation, in the above haptic feedback panel provided by an embodiment of the present disclosure, a plurality of first piezoelectric devices are provided, a plurality of second piezoelectric devices are provided, the plurality of first piezoelectric devices are arranged in an array on the non-touch surface of the touch substrate, the plurality of second piezoelectric devices are arranged in an array on the non-touch surface of the touch substrate, and columns of the first piezoelectric devices and columns of the second piezoelectric devices are alternately arranged.

In a possible implementation, in the above haptic feedback panel provided by an embodiment of the present disclosure, the first piezoelectric device includes a first electrode, the first piezoelectric layer, and a second electrode that are stacked; and the first electrode is in contact with the non-touch surface of the touch substrate. The first piezoelectric layer has a first surface in contact with the second electrode, and the first electrode has a first end extending along a side edge of the first piezoelectric layer to the first surface. The first end is electrically connected to a first voltage detection terminal, and the second electrode is electrically connected to a second voltage detection terminal.

In a possible implementation, in the above haptic feedback panel provided by an embodiment of the present disclosure, in all of the first piezoelectric devices, first ends of all first electrodes are electrically connected to the first voltage detection terminals, and all second electrodes are electrically connected to the second voltage detection terminals.

In a possible implementation, in the above haptic feedback panel provided by an embodiment of the present disclosure, in a same row of the first piezoelectric devices, first ends of all first electrodes are electrically connected to a same first voltage detection terminal, and all second electrodes are electrically connected to a same second voltage detection terminal; and in different rows of the first piezoelectric devices, first ends of the first electrodes are electrically connected to different first voltage detection terminals, and the second electrodes are electrically connected to different second voltage detection terminals.

In a possible implementation, in the above haptic feedback panel provided by an embodiment of the present disclosure, the first end of the first electrode is electrically connected to the first voltage detection terminal via a first lead, and the second electrode is electrically connected to the second voltage detection terminal via a second lead; and both the first lead and the second lead include a conductive wire and an insulating film wrapping the conductive wire.

In a possible implementation, in the above haptic feedback panel provided by an embodiment of the present disclosure, in one second piezoelectric device, for all of the electrode layers, odd-numbered electrode layers are electrically connected to each other, even-numbered electrode layers are electrically connected to each other, and the odd-numbered electrode layers and the even-numbered electrode layers are insulated from each other.

In a possible implementation, in the above haptic feedback panel provided by an embodiment of the present disclosure, the second piezoelectric device further includes a first conductive portion and a second conductive portion extending in a thickness direction of the haptic feedback panel, and the first conductive portion and the second conductive portion are disposed on two opposite sides of the second piezoelectric layer. The odd-numbered electrode layers are electrically connected through the first conductive portion, and the even-numbered electrode layers are electrically connected through the second conductive portion.

In a possible implementation, in the above haptic feedback panel provided by an embodiment of the present disclosure, the first conductive portion has a second end extending to a bottom surface of the bottom second piezoelectric layer that is closest to the non-touch surface, and the second conductive portion has a third end extending to a top surface of the top second piezoelectric layer that is farthest away from the non-touch surface. The third end is electrically connected to a ground terminal, and the electrode layer of the odd-numbered electrode layers farthest away from the non-touch surface is electrically connected to a drive signal terminal.

In a possible implementation, in the above haptic feedback panel provided by an embodiment of the present disclosure, in all of the second piezoelectric devices, third ends of all second conductive portions are electrically connected to a same ground terminal, and the electrode layers in the odd-numbered electrode layers that are farthest away from the non-touch surface are electrically connected to a same drive signal terminal.

In a possible implementation, in the above haptic feedback panel provided by an embodiment of the present disclosure, in all of the second piezoelectric devices, third ends of all second conductive portions are electrically connected to a same ground terminal; in the same row of the second piezoelectric devices, the electrode layers of the odd-numbered electrode layers that are farthest away from the non-touch surface are all electrically connected to a same drive signal terminal; and in different rows of the second piezoelectric devices, the electrode layers of the odd-numbered electrode layers that are farthest away from the non-touch surface are electrically connected to different drive signal terminals.

In a possible implementation, in the above haptic feedback panel provided by an embodiment of the present disclosure, a third end of the second conductive portion is electrically connected to the ground terminal via a third lead, and the electrode layer of the odd-numbered electrode layers that is farthest away from the non-touch surface is electrically connected to the drive signal terminal via a fourth lead; and both the third lead and the fourth lead include a conductive wire and an insulating film wrapping the conductive wire.

In a possible implementation, in the above haptic feedback panel provided by an embodiment of the present disclosure, a spacing between two adjacent columns of the first piezoelectric devices ranges from 20 mm to 30 mm, and a spacing between two adjacent first piezoelectric devices in a same column ranges from 20 mm to 30 mm; and a spacing between two adjacent columns of the second piezoelectric devices ranges from 20 mm to 30 mm, and a spacing between two adjacent second piezoelectric devices in a same column ranges from 20 mm to 30 mm.

In a possible implementation, in the above haptic feedback panel provided by an embodiment of the present disclosure, an area of the first piezoelectric device ranges from 50 mm² to 150mm², and a shape of the first piezoelectric device includes a rectangle, a square or a circle; and an area of the second piezoelectric device ranges from 50 mm² to 150 mm², and a shape of the second piezoelectric device includes a rectangle, a square or a circle.

In a possible implementation, in the above haptic feedback panel provided by an embodiment of the present disclosure, a thickness of the first piezoelectric layer is the same as a total thickness of the second piezoelectric layers.

In a possible implementation, in the above haptic feedback panel provided by an embodiment of the present disclosure, the thickness of the first piezoelectric layer ranges from 0.3 mm to 0.6 mm and the total thickness of the second piezoelectric layers ranges from 0.3 mm to 0.6 mm.

In a possible implementation, in the above haptic feedback panel provided by an embodiment of the present disclosure, the thickness of each of the second piezoelectric layers is substantially the same, and the thickness of each of the second piezoelectric layers is less than or equal to 100 μm.

In a possible implementation, in the above haptic feedback panel provided by an embodiment of the present disclosure, the thickness of each of the second piezoelectric layers ranges from 10 μm to 30 μm.

In a possible implementation, in the above haptic feedback panel provided by an embodiment of the present disclosure, a layer number of the second piezoelectric layers ranges from 2 to 20.

In a possible implementation, in the above haptic feedback panel provided by an embodiment of the present disclosure, materials of the electrode layer include silver, silver palladium, platinum, and gold.

In a possible implementation, in the above haptic feedback panel provided by an embodiment of the present disclosure, the touch substrate includes a display substrate and a touch layer on a side of a display surface of the display substrate, and the first piezoelectric device and the second piezoelectric device are both disposed on the non-display surface of the display substrate.

In a possible implementation, in the above haptic feedback panel provided by an embodiment of the present disclosure, the touch layer includes a first metal layer, an insulating layer, and a second metal layer that are stacked; the first metal layer includes bridging electrodes; the second metal layer includes: a plurality of first touch electrodes arranged in a row direction, a plurality of second touch electrodes arranged in a column direction, and a connection electrode between two adjacent first touch electrodes; the plurality of first touch electrodes are electrically connected in pairs through a corresponding connection electrode, respectively; and each of the plurality of second touch electrodes is electrically connected to a corresponding bridging electrode through a via hole penetrating the insulating layer.

In a possible implementation, the above haptic feedback panel provided by an embodiment of the present disclosure further includes a circuit control board on one sides of the first piezoelectric device and the second piezoelectric device away from the touch substrate; the circuit control board includes a pressure detector, a pressure judging device, and a drive signal outputter; the pressure detector is electrically connected to a pressure detection terminal; the pressure judging device is electrically connected to the pressure detector; and the drive signal outputter is electrically connected to the pressure judging device and the drive signal terminal.

In a possible implementation, the above haptic feedback panel provided by an embodiment of the present disclosure further includes a base shell on a side of the circuit control board away from the touch substrate.

Correspondingly, an embodiment of the present disclosure further provides a haptic feedback apparatus, including the above haptic feedback panel provided by the embodiments of the present disclosure.

Correspondingly, an embodiment of the present disclosure further provides a method for driving the above haptic feedback panel provided by the embodiments of the present disclosure, including: when a user presses a surface of the touch substrate and the first piezoelectric device deforms to generate a voltage, detecting a magnitude of a pressing force corresponding to the voltage; in response to the pressing force being greater than or equal to a threshold value, loading an alternating current signal to the second piezoelectric device to cause the second piezoelectric device to vibrate under an action of an alternating electric field, driving the touch substrate to resonate, and realizing haptic feedback; and in response to the pressing force being less than the threshold value, not needing to load an alternating current signal to the second piezoelectric device.

### BRIEF DESCRIPTION OF FIGURES

FIG. 1 is a schematic diagram of a three-dimensional structure of a haptic feedback panel provided by an embodiment of the present disclosure.

FIG. 2 is a schematic diagram of a planar structure of a haptic feedback panel provided by an embodiment of the present disclosure.

FIG. 3 is a schematic diagram of a partial structure in FIG. 2.

FIG. 4 is a schematic diagram of a partial structure in FIG. 2.

FIG. 5 is a schematic diagram of a cross-section along a direction AA′ in FIG. 2.

FIG. 6 is a schematic diagram of a cross-section along a direction BB′ in FIG. 2.

FIG. 7 is a schematic diagram of driving of a first piezoelectric device.

FIG. 8 is another schematic diagram of driving of a first piezoelectric device.

FIG. 9 is a schematic diagram of driving of a second piezoelectric device.

FIG. 10 is another schematic diagram of driving of a second piezoelectric device.

FIG. 11 is a schematic diagram of an output voltage of a single-layer first piezoelectric device under a trigger force (pressing force) of 100 g.

FIG. 12 is a schematic diagram of an output voltage of a multi-layer second piezoelectric device under a trigger force of 100 g.

FIG. 13 is a schematic diagram of longitudinal vibration displacement (D_{P-P}) of a single-layer first piezoelectric device and a multi-layer second piezoelectric device vibrating under the same alternating electric field.

FIG. 14 is another schematic diagram of a three-dimensional structure of a haptic feedback panel provided by an embodiment of the present disclosure.

FIG. 15 is a planar schematic diagram of a touch layer.

FIG. 16 is a schematic diagram of a cross-section along a direction CC′ in FIG. 15.

FIG. 17 is another schematic diagram of a three-dimensional structure of a haptic feedback panel provided by an embodiment of the present disclosure.

FIG. 18 is a schematic structural diagram of a circuit control board.

FIG. 19 is a schematic flow diagram of a working principle of a haptic feedback panel.

FIG. 20 is a flow chart of a driving method of a haptic feedback panel provided by an embodiment of the present disclosure.

### DETAILED DESCRIPTION

In order to make the objects, technical solutions and advantages of the embodiments of the present disclosure clearer, the technical solutions of the embodiments of the present disclosure will be described clearly and completely in the following in conjunction with the accompanying drawings of the embodiments of the present disclosure. Obviously, the described embodiments are a part of the embodiments of the present disclosure and not all of the embodiments. And the embodiments and the features in the embodiments of the present disclosure can be combined with each other without conflict. Based on the described embodiments of the present disclosure, all other embodiments obtained by a person of ordinary skill in the art without creative labors are within the protection scope of the present disclosure.

Unless otherwise defined, technical terms or scientific terms used in the present disclosure shall have the ordinary meaning understood by a person of ordinary skill in the art to which the present disclosure belongs. The words “including” or “comprising” and the like as used in the present disclosure mean that the element or object appearing before the word covers the element or object appearing after the word and their equivalents, without excluding other elements or objects. Words such as “connected” or “coupled” are not limited to physical or mechanical connections, but may include electrical connections, whether direct or indirect. The words “inside”, “outside”, “above”, “below” and the like are used only to indicate relative positional relationships. When the absolute position of the described object is changed, the relative positional relationships may also be changed accordingly.

It should be noted that the dimensions and shapes of the figures in the accompanying drawings do not reflect true proportions and are intended to illustrate the present disclosure only. And throughout the same or similar reference numerals denote the same or similar elements or elements having the same or similar functions.

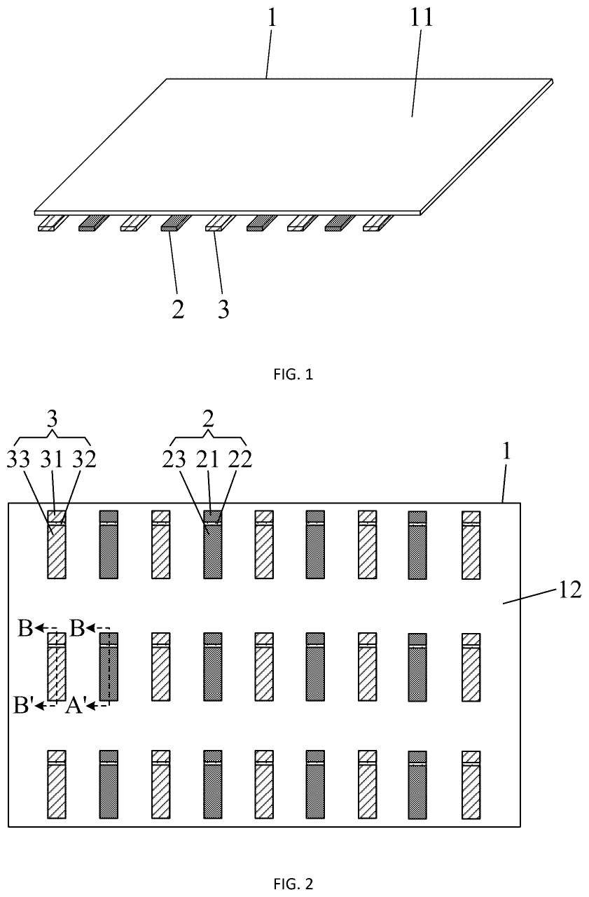

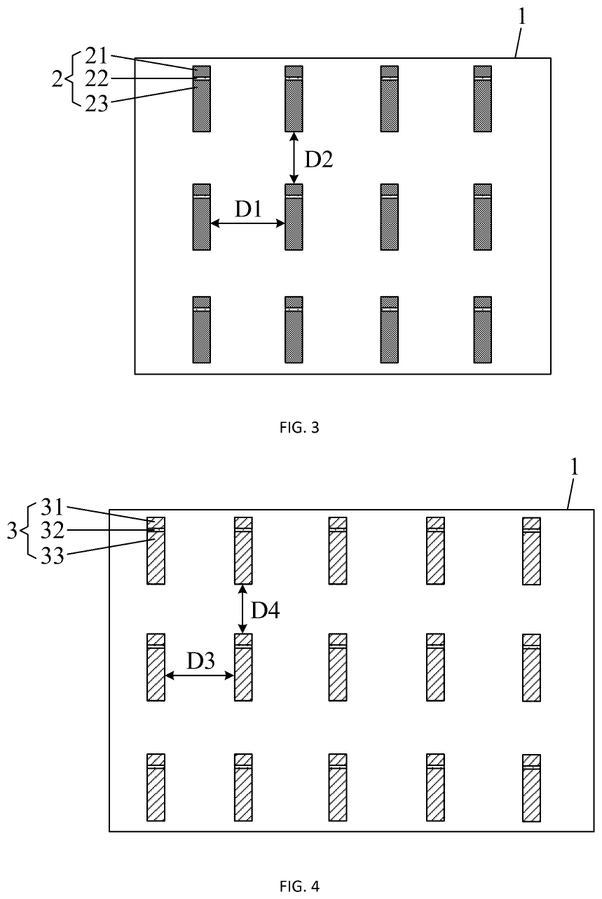

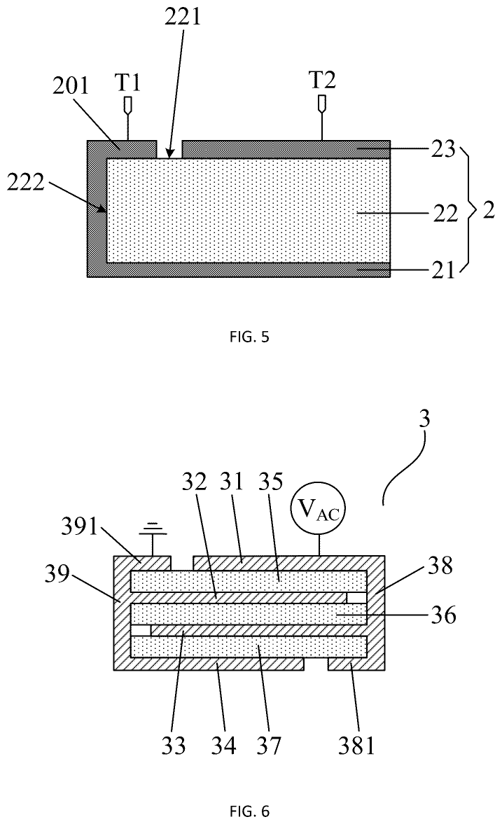

Embodiments of the present disclosure provide a haptic feedback panel as shown in FIGS. 1-FIG. 6. FIG. 1 is a schematic diagram of a three-dimensional structure of a haptic feedback panel, FIG. 2 is a schematic diagram of a planar structure of a haptic feedback panel, FIG. 3 is a schematic diagram of a part of the structure of FIG. 2, FIG. 4 is a schematic diagram of a part of the structure of FIG. 2, FIG. 5 is a schematic diagram of a cross-section along the direction AA′ in FIG. 2, and FIG. 6 is a schematic diagram of a cross-section along the direction BB′ in FIG. 2. The haptic feedback panel includes:
a touch substrate 1;
at least one first piezoelectric device 2 on the touch substrate 1; where the first piezoelectric device 2 includes a single first piezoelectric layer 22, and the first piezoelectric device 2 is configured to detect pressure pressed onto a surface of the touch substrate 1; and
at least one second piezoelectric device 3 on the touch substrate 1; where the second piezoelectric device 3 includes at least three electrode layers that are stacked (the present disclosure takes four electrode layers as an example, 31, 32, 33, and 34, respectively), and a second piezoelectric layer (35, 36, or 37) between every two adjacent electrode layers; and the second piezoelectric device 3 is configured to vibrate under the action of an alternating electric field, and to drive the touch substrate 1 to resonate.

In the above haptic feedback panel provided by embodiments of the present disclosure, the single-layer first piezoelectric device is adopted to detect the pressure of a finger pressing onto the surface of the touch substrate. Compared to the multi-layer piezoelectric device, when pressing the single-layer piezoelectric device, the pressure per unit can generate a larger output voltage, which is conducive to improving the signal-to-noise ratio of the output voltage, facilitating the signal identification and processing of the circuit system, and improving the sensitivity of the pressure detection. The multi-layer second piezoelectric device is adopted to drive the overall resonance of the touch substrate, to generate vibration sensation, and realize haptic feedback. Since the second piezoelectric device includes at least three electrode layers that are stacked, then the second piezoelectric device includes at least two second piezoelectric layers, and thus the second piezoelectric device is equivalent to including at least two piezoelectric structures arranged in parallel. The overall driving voltage of the second piezoelectric device is equal to the single-layer driving voltage, and the haptic feedback strengths of the second piezoelectric layers in the parallel structure can be superimposed. Therefore, compared to the related art in which a thicker piezoelectric layer needs to be set in order to improve the haptic feedback strength, which leads to the problem of a high driving voltage loaded in the related art, in the embodiments of the present disclosure, by setting the sum of the thicknesses of the second piezoelectric layers equal to the thickness of a whole layer in the related art, a haptic feedback strength same as that in the related art can be achieved. For example, three second piezoelectric layers are provided, so that the driving voltage corresponding to each second piezoelectric layer can be reduced to one-third of that in the related art. Therefore, the haptic feedback panel provided in embodiments of the present disclosure adopts the single-layer first piezoelectric device to improve the sensitivity of pressure detection, and adopts the multi-layer second piezoelectric device to realize vibration feedback driven by a low voltage.

In specific implementation, in the above haptic feedback panel provided by embodiments of the present disclosure, as shown in FIGS. 1 and 2, the touch substrate 1 has a touch surface 11 and a non-touch surface 12 opposite to each other, the first piezoelectric devices 2 and the second piezoelectric devices 3 are on the non-touch surface 12 of the touch substrate 1, and an orthographic projection(s) of the first piezoelectric device(s) 2 on the touch substrate 1 and an orthographic projection(s) of the second piezoelectric device(s) 3 on the touch substrate 1 do not overlap. This achieves separate pressure detection and vibration feedback, improves the sensitivity of pressure detection and realizes vibration feedback driven by a low voltage.

In specific implementation, in the above haptic feedback panel provided by embodiments of the present disclosure, as shown in FIG. 2, there are a plurality of first piezoelectric devices 2 and a plurality of second piezoelectric device 3, to further improve the sensitivity of the pressure detection and the vibrational feedback effect. The plurality of first piezoelectric devices 2 are arranged in array on the non-touch surface 12 of the touch panel substrate 1, the plurality of second piezoelectric devices 3 are arranged in array on the non-touch surface 12 of the touch substrate 1, and columns of the first piezoelectric devices 2 and columns of the second piezoelectric devices 3 are alternately arranged. This allows the non-touch surface 12 of the touch substrate 1 to be uniformly distributed with the first piezoelectric devices 2 for pressure detection and the second piezoelectric devices 3 for haptic feedback, improving the accuracy of the pressure detection and improving the haptic feedback effect.

Of course, in specific implementation, the first piezoelectric devices 2 and the second piezoelectric devices 3 are not limited to the arrangement of FIG. 2, and as long as the non-touch surface 12 of the touch substrate 1 is provided with the first piezoelectric devices 2 and the second piezoelectric devices 3, they fall within the protection scope of the present disclosure.

In specific implementation, in the above haptic feedback panel provided by embodiments of the present disclosure, as shown in FIGS. 2, 3, and 5, the first piezoelectric device 2 includes a first electrode 21, a first piezoelectric layer 22, and a second electrode 23 that are stacked; and the first electrode 21 is in contact with the non-touch surface 12 of the touch substrate 1. The first piezoelectric layer 22 has a first surface 221 in contact with the second electrode 23, and the first electrode 21 has a first end 201 extending along a side edge 222 of the first piezoelectric layer 22 to the first surface 221; where, the first end 201 is electrically connected to the first voltage detection terminal T1, and the second electrode 23 is electrically connected to the second voltage detection terminal T2.

Specifically, the first electrode 21 is led out from the side edge of the first piezoelectric layer 22 to the first surface 221, so that a flat first electrode 21 is attached with the touch substrate 1, and the lead wire electrically connected to the first electrode 21 can be led out from the first end 201, to facilitate the flat attachment and wiring of the first piezoelectric device 2. Optionally, the preparation method of the first electrodes 21 and the second electrodes 23 includes processes such as screen printing, chemical deposition, and vacuum coating.

Specifically, the working process of the first piezoelectric device is as follows: when a finger contacts the surface of the touch substrate and applies a certain amount of pressing force, the touch substrate deforms and drives the first piezoelectric layer to deform, two ends of the first piezoelectric device generate a voltage difference by utilizing the positive piezoelectric effect, and the voltage difference is detected through the voltage detection terminal to realize the pressure detection function, here, the voltage difference has a positive linear relationship with the trigger force of the finger.

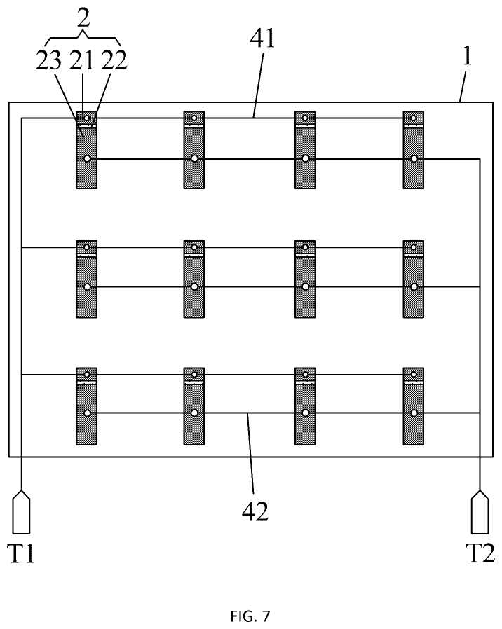

In specific implementation, in the above haptic feedback panel provided by embodiments of the present disclosure, as shown in FIG. 7, in all of the first piezoelectric devices 2, the first ends 201 of all first electrodes 21 are electrically connected to the first voltage detection terminals T1, and all second electrodes 23 are electrically connected to the second voltage detection terminals T2. In this way, all the first piezoelectric devices 2 are connected in parallel, and the pressing force of the finger can be detected by a circuit.

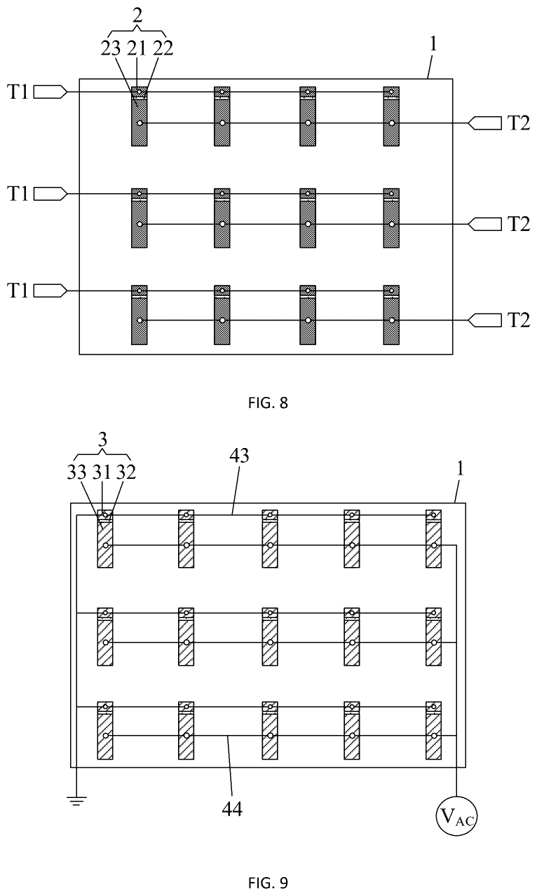

In specific implementation, in the above haptic feedback panel provided by embodiments of the present disclosure, as shown in FIG. 8, in the same row of the first piezoelectric devices 2, the first ends 201 of all first electrodes 21 are electrically connected to the same first voltage detection terminal T1, and all second electrodes 23 are electrically connected to the same second voltage detection terminal T2; and
in different rows of the first piezoelectric devices 2, the first ends 201 of the first electrodes 21 are electrically connected to different first voltage detection terminals T1, and the second electrodes 23 are electrically connected to different second voltage detection terminals T2. In this way, the first piezoelectric devices 2 in each row are connected in parallel, realizing the detection of the pressing force of the finger in a single row.

Of course, in specific implementation, the detection of the pressing force of the finger is not limited to the detection method of FIGS. 7 and 8, but it can also be that each piezoelectric device is individually detected and a single column of piezoelectric devices are detected, etc., which are selected according to actual needs.

In specific implementation, in the above haptic feedback panel provided by embodiments of the present disclosure, as shown in FIGS. 7 and 8, the first end 201 of the first electrode 21 is electrically connected to the first voltage detection terminal T1 via the first lead 41, and the second electrode 23 is electrically connected to the second voltage detection terminal T2 via the second lead 42.

The first lead 41 and the second lead 42 both include a conductive wire and an insulating film wrapping the conductive wire, such that the conductive wire is only exposed at a position of the first lead 41 electrically connected to the first end 201, and the insulating film is provided at the remaining position of the first lead 41; and the conductive wire is only exposed at a position of the second lead 42 electrically connected to the second electrode 23, and the insulating film is provided at the remaining position of the second lead 42, which can avoid the first leads 41 and the second leads 42 from short-circuiting with the second piezoelectric devices 3 and the other leads.

In specific implementation, in the above haptic feedback panel provided by embodiments of the present disclosure, as shown in FIG. 3, a spacing D1 between two adjacent columns of the first piezoelectric devices 2 may range from 20 mm to 30 mm, and a spacing D2 between two adjacent first piezoelectric devices 2 in the same column may range from 20 mm to 30 mm. In this way, the first piezoelectric devices 2 may be uniformly distributed on a non-touch surface of the touch substrate 1, improving the pressure detection effect.

In specific implementation, in the above haptic feedback panel provided by embodiments of the present disclosure, as shown in FIG. 3, an area of the first piezoelectric device 2 may range from 50 mm 2 to 150mm 2 . If the area of the first piezoelectric device 2 is small, the output voltage generated by the pressing force will be small, and the signal-to-noise ratio of the circuit is poor, which is unfavorable for detection. If the area of the first piezoelectric device 2 is too large, the stiffness of the first piezoelectric device 2 will constrain the resonant mode of the touch substrate, which is unfavorable for vibration starting.

In specific implementation, in the above haptic feedback panel provided by embodiments of the present disclosure, as shown in FIG. 3, the shape of the first piezoelectric device 2 may be a rectangle; and of course, the shape of the first piezoelectric device 2 may be a square or a circle.

In specific implementation, in the above haptic feedback panel provided by embodiments of the present disclosure, as shown in FIG. 6, in one second piezoelectric device 3, for all the electrode layers (31, 32, 33, and 34), the odd-numbered electrode layers (31 and 33) are electrically connected to each other, the even-numbered electrode layers (32 and 34) are electrically connected to each other, and the odd-numbered electrode layers (31 and 33) and the even-numbered electrode layers (32 and 34) are insulated from each other. Specifically, each of the odd-numbered electrode layers (31 and 33) may be a negative electrode, and each of the even-numbered electrode layers (32 and 34) is a positive electrode. Of course, it is also possible that each of the odd-numbered electrode layers (31 and 33) is a positive electrode and each of the even-numbered electrode layers (32 and 34) is a negative electrode. Specifically, the embodiments of the present disclosure are described by an example in which each of the odd-numbered electrode layers (31 and 33) is a positive electrode and each of the even-numbered electrode layers (32 and 34) is a negative electrode.

In specific implementation, in the above haptic feedback panel provided in the present embodiments of the disclosure, as shown in FIG. 6, the second piezoelectric device 3 further includes a first conductive portion 38 and a second conductive portion 39 extending in the thickness direction of the haptic feedback panel, and the first conductive portion 38 and the second conductive portion 39 are disposed on two opposite sides of the second piezoelectric layers (35, 36, and 37). The odd-numbered electrode layers (31 and 33) are electrically connected via the first conductive portion 38, and the even-numbered electrode layers (32 and 34) are electrically connected via the second conductive portion 39.

In specific implementation, in the above haptic feedback panel provided in embodiments of the present disclosure, as shown in FIG. 6, the first conductive portion 38 has a second end 381 extending to a bottom surface of the bottom second piezoelectric layer 37 that is closest to the non-touch surface 12, and the second conductive portion 39 has a third end 391 extending to a top surface of the top second piezoelectric layer 35 that is farthest away from the non-touch surface 12. The third end 391 is electrically connected to the ground terminal, and the electrode layer 31 of the odd-numbered electrode layers (31 and 33) farthest away from the non-touch surface 12 is electrically connected to the drive signal terminal VAC.

Specifically, a working process of the second piezoelectric device 3 is as follows: the third end 391 of the second conductive portion 39 is grounded by utilizing the inverse piezoelectric effect, by loading a high-frequency alternating current voltage signal (V_{AC}) into the electrode layer 31 of the odd-numbered electrode layers (31 and 33) farthest away from the non-touch surface, an alternating electric field is formed between the respective electrode layers, and the second piezoelectric layers (35, 36, and 37) are subjected to polarization deformation under the action of the alternating electric field to generate vibration displacement, to realize the haptic feedback effect such as force and vibration feedback, and texture reproduction.

In specific implementation, in the above haptic feedback panel provided in the embodiments of the present disclosure, as shown in FIG. 9, in all the second piezoelectric devices 3, the third ends 391 of all the second conductive portions 39 are electrically connected to the same ground terminal, and the electrode layers 31 of the odd-numbered electrode layers (31 and 33) farthest away from the non-touch surface 12 are all electrically connected to the same drive signal terminal VAC. In this way, all the second piezoelectric devices 3 are connected in parallel, and can be driven by a circuit.

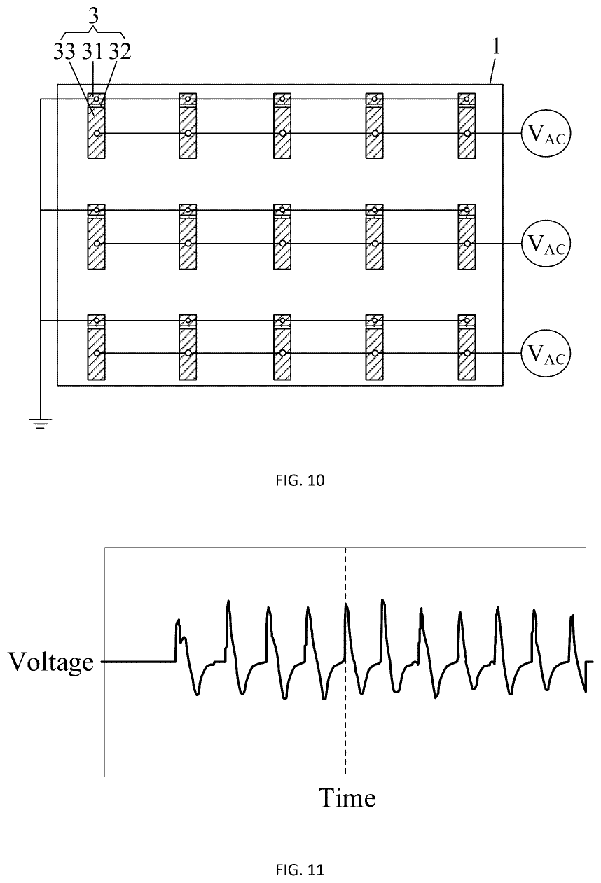

In specific implementation, in the above haptic feedback panel provided by embodiments of the present disclosure, as shown in FIG. 10, in all the second piezoelectric devices 3, the third ends 391 of all the second conductive portions 39 are electrically connected to the same ground terminal;
in the same row of second piezoelectric devices 3, the electrode layers 31 of the odd-numbered electrode layers (31 and 33) that are farthest away from the non-touch surface 12 are all electrically connected to the same drive signal terminal VAC; and
in different rows of second piezoelectric devices 3, the electrode layers 31 of the odd-numbered electrode layers (31 and 33) that are farthest away from the non-touch surface 12 are electrically connected to different drive signal terminals VAC. In this way, the second piezoelectric devices 3 in each row are connected in parallel, to realize row driving.

Of course, in specific implementation, the driving method for realizing haptic feedback is not limited to the driving method of FIGS. 9 and 10, but it can also be that each piezoelectric device is individually driven, and a single column of piezoelectric devices are driven, etc., which are selected according to actual needs.

In specific implementation, in the above haptic feedback panel provided by embodiments of the present disclosure, as shown in FIGS. 9 and 10, the third end 391 of the second conductive portion 39 is electrically connected to the ground terminal via the third lead 43, and the electrode layer 31 of the odd-numbered electrode layers (31 and 33) farthest away from the non-touch surface is electrically connected to the drive signal terminal VAC via the fourth lead 44.

The third lead 43 and the fourth lead 44 both include a conductive wire and an insulating film wrapping the conductive wire, such that the conductive wire is only exposed at a position of the third lead 43 electrically connected to the third end 391, and the insulating film is provided at the remaining position of the third lead 43; and the conductive wire is only exposed at a position of the fourth lead 44 electrically connected to the electrode layer 31, and the insulating film is provided at the remaining position of the fourth lead 44, which can avoid the third leads 43 and the fourth leads 44 from short-circuiting with the first piezoelectric devices 2 and the other leads.

In specific implementation, in the above haptic feedback panel provided by embodiments of the present disclosure, as shown in FIG. 6, the electrode layer 31 farthest away from the non-touch surface has a gap with the third end 391, and the electrode layer 34 closest to the non-touch surface has a gap with the second end 381, so as to avoid short-circuiting between the odd-numbered electrode layers (31 and 33) and the even-numbered electrode layers (32 and 34).

Optionally, the preparation method of each electrode layer (31, 32, 33 and 34) includes processes such as screen printing, chemical deposition and vacuum coating.

In specific implementation, in the above-described haptic feedback panel provided by embodiments of the present disclosure, as shown in FIG. 4, a spacing D3 between two adjacent columns of the second piezoelectric devices 3 may range from 20 mm to 30 mm, and a spacing D3 between two adjacent second piezoelectric devices 3 in the same column may range from 20 mm to 30 mm. In this way, the second piezoelectric devices 3 may be uniformly distributed on a non-touch surface of the touch substrate 1, improving the haptic feedback effect.

In specific implementation, in the above haptic feedback panel provided by embodiments of the present disclosure, as shown in FIG. 4, an area of the second piezoelectric device 3 may range from 50 mm² to 150 mm².

In specific implementation, in the above haptic feedback panel provided by embodiments of the present disclosure, as shown in FIG. 4, the shape of the second piezoelectric device 3 may be a rectangle, and of course, the shape of the second piezoelectric device 3 may also be a square or a circle.

In specific implementation, in the above haptic feedback panel provided by embodiments of the present disclosure, as shown in FIGS. 5 and 6, a thickness of the first piezoelectric layer 22 and a total thickness of the respective second piezoelectric layers (35, 36, and 37) may be the same.

In specific implementation, in the above-described haptic feedback panel provided by embodiments of the present disclosure, as shown in FIG. 5, the thickness of the first piezoelectric layer 22 may range from 0.3 mm to 0.6 mm, for example, the thickness of the first piezoelectric layer 22 may be 0.3 mm, 0.4 mm, 0.5 mm, or 0.6 mm.

In specific implementation, in the above haptic feedback panel provided in embodiments of the present disclosure, as shown in FIG. 6, the total thickness of the respective second piezoelectric layers (35, 36, and 37) may range from 0.3 mm to 0.6 mm, for example, the total thickness of the respective second piezoelectric layers (35, 36, and 37) may be 0.3 mm, 0.4 mm, 0.5 mm, or 0.6 mm.

In specific implementation, in the above haptic feedback panel provided in embodiments of the present disclosure, as shown in FIG. 6, the thicknesses of the respective second piezoelectric layers (35, 36, and 37) are substantially the same, and the thickness of each of the second piezoelectric layers (35, 36, and 37) is less than or equal to 100 μm.

In specific implementation, in the above haptic feedback panel provided in embodiments of the present disclosure, the thickness of each of the second piezoelectric layers (35, 36 and 37) may range from 10 μm to 30 μm, as shown in FIG. 6.

In specific implementation, when the total thickness of the multiple second piezoelectric layers is equal to the total thickness of the single piezoelectric layer, the driving voltage V₁ of the multiple second piezoelectric layers and the driving voltage V₂ of the single piezoelectric layer satisfy the relational equation: V₁=V₂/N, where N is the layer number of the multiple second piezoelectric layers. Based on this, the overall driving voltage of the second piezoelectric device 3 can be effectively reduced.

Specifically, as shown in FIG. 6, when applying the driving voltage to the odd-numbered electrode layers (31 and 33) and the even-numbered electrode layers (32 and 34), since a thicker piezoelectric layer in the related art is split into three layers in FIG. 6 of the embodiments of the present disclosure, such that the driving voltage V₁ of the multiple piezoelectric layers can be reduced to one-third of the driving voltage V₂ of the single piezoelectric layer in the related art, i.e. V₁=V₂/3. The vibration effects of the respective second piezoelectric layers (35, 36, and 37) can be superimposed on each other, so that the embodiments of the present disclosure greatly reduce the driving voltage of the haptic feedback panel on the basis of improving the haptic feedback strength of the haptic feedback panel.

In specific implementation, in the above haptic feedback panel provided by embodiments of the present disclosure, the layer number of the second piezoelectric layers may range from 2 to 20. In FIG. 6 of embodiments of the present disclosure, three second piezoelectric layers are taken as an example. Of course, the embodiments of the present disclosure do not limit the layer number of the second piezoelectric layers, and the principle and the realization method are the same for different numbers of stacked layers.

In specific implementation, the materials of the above first electrodes, the second electrodes and each electrode layer may include silver, silver palladium, platinum, and gold. Of course, they can also be made of indium tin oxide (ITO), and they can also be made of indium zinc oxide (IZO). Of course, they can also be made of one of titanium-gold (Ti—Au) alloy, titanium-aluminum-titanium (Ti—AI—Ti) alloy, or titanium-molybdenum (Ti—Mo) alloy. Furthermore, they can also be made of one of titanium (Ti), molybdenum (Mo), copper (Cu), tungsten (W), or chromium (Cr). The skilled in the art may set the above first electrodes, the second electrodes, and each electrode layer according to practical application needs, and there is no limitation here.

In specific implementation, the material of the piezoelectric layer may be lead zirconate titanate (Pb(Zr,Ti)O₃, PZT), and may also be at least one of aluminum nitride (AlN), zinc oxide (ZnO), barium titanate (BaTiO₃), lead titanate (PbTiO₃), potassium niobate (KNbO₃), lithium niobate (LiNbO₃), lithium tantalate (LiTaO₃), or lanthanum gallium silicate (La₃Ga, SiO₁₄). The material for fabricating the piezoelectric layer can be selected according to the actual use needs of the skilled in the art, and is not limited herein. When the piezoelectric layer is fabricated by using PZT, the piezoelectric characteristics of the corresponding piezoelectric sensor are ensured due to the high piezoelectric coefficient of PZT, which allows the corresponding piezoelectric sensor to be applied to a haptic feedback apparatus. Moreover, PZT has the high light transmission, which does not affect the display quality of the display device when it is integrated into the display device.

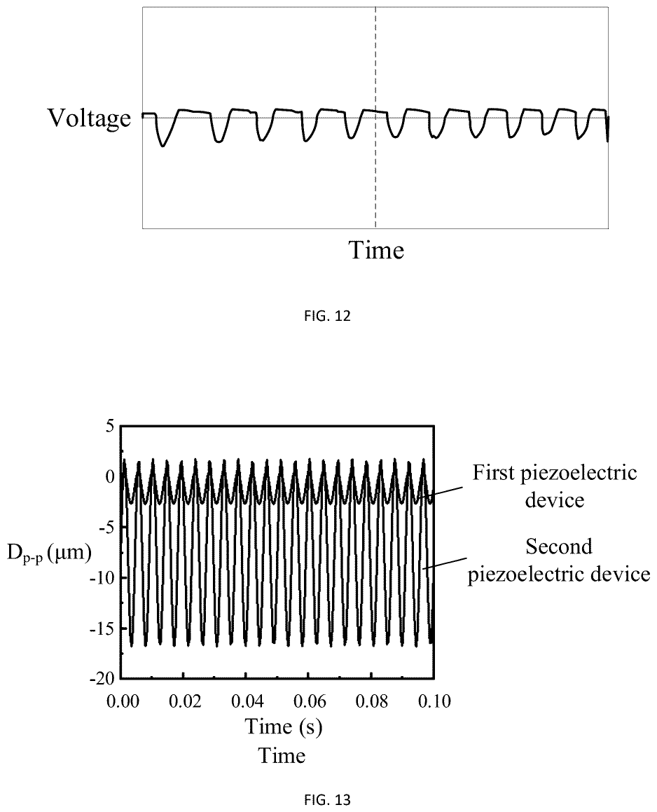

As shown in FIG. 11 and FIG. 12, FIG. 11 is a schematic diagram of the output voltage of the single-layer first piezoelectric device under a trigger force (pressing force) of 100 g, and FIG. 12 is a schematic diagram of the output voltage of the multi-layer second piezoelectric device under a trigger force of 100 g. It can be seen that, with the same trigger force, it is apparent that the single-layer first piezoelectric device outputs a larger voltage, which is more conducive to the voltage detection of the circuit, improving the sensitivity of pressure detection.

As shown in FIG. 13, FIG. 13 is a schematic diagram of the longitudinal vibration displacement (D_{P-P}) of the single-layer first piezoelectric device and the multi-layer second piezoelectric device vibrating under the action of the same alternating electric field. It can be seen that, for the same driving voltage, the vibration displacement of the multi-layer second piezoelectric device is significantly higher than the vibration displacement of the single-layer first piezoelectric device. Therefore, for the same vibration displacement, the driving voltage applied to the multi-layer second piezoelectric device will be significantly lower than the driving voltage of the single-layer first piezoelectric device.

Specifically, for the single-layer first piezoelectric device 2 shown in FIG. 5, when an alternating current is applied to the first electrode 21 and the second electrode 23 thereof, the change of the longitudinal vibrational displacement is Δl=d33*E*h1, where d33 is the piezoelectric constant, E is the maximum value of the applied electric field, and h1 is the thickness of the single-layer first piezoelectric layer 22. Herein, the applied voltage V₁=E*h1.

FIG. 6 shows a multi-layer second piezoelectric device 3 including a plurality of electrode layers in a structural series and electrical parallel manner. When the second piezoelectric layer is subject to pre-polarization, the adjacent second piezoelectric layer has an opposite polarization direction. When an electrical signal is applied to each electrode layer, the change of the longitudinal vibrational displacement is Δ2=d33*E*h2*N, where h2 is the thickness of each second piezoelectric layer, N is the layer number of the second piezoelectric layers, and the applied voltage is V₂=E*h2. Since h1=N*h2, when the thickness of the first piezoelectric layer is the same as the overall thickness of the respective second piezoelectric layers, the driving voltage of the multi-layer second piezoelectric device is V₂=V₁/N. Thus, the use of the multi-layer second piezoelectric device can realize vibration feedback driven by a low voltage.

In specific implementation, in the above haptic feedback panel provided by embodiments of the present disclosure, as shown in FIG. 1, the touch substrate 1 may be a usual metal touch panel or a display screen such as an organic light-emitting diode (OLED) screen, a liquid crystal display (LCD) screen, and the like.

Specifically, when the touch substrate is an OLED display screen, the OLED display screen may be a 5.5-inch screen with a length and width of 70 mm×128 mm, respectively. The area of the first piezoelectric device and the area of the second piezoelectric device may be 5 mm*20 mm.

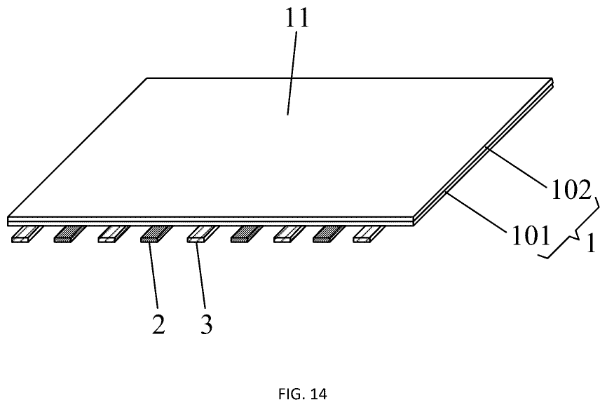

In specific implementation, in the above haptic feedback panel provided by embodiments of the present disclosure, when the touch substrate is a display screen, as shown in FIG. 14, the touch substrate 1 may include a display substrate 101 and a touch layer 102 disposed on a side of a display surface of the display substrate 101, and the first piezoelectric devices 2 and the second piezoelectric devices 3 are disposed on a non-display surface of the display substrate 101. Specifically, a user's finger touches the surface of the touch substrate 1, and the touch position of the finger is localized by a change in capacitance. When the touch substrate is a display screen, because the touch substrate has a display function, the touch substrate can also be used as a sub-screen of the laptop screen to output a prompt graphic.

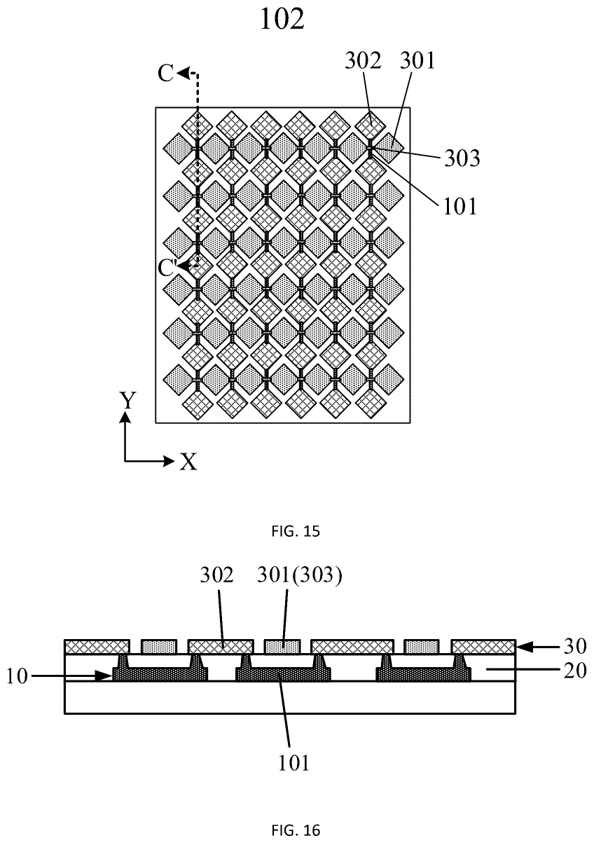

In specific implementation, in the above haptic feedback panel provided by embodiments of the present disclosure, as shown in FIG. 15 and FIG. 16, FIG. 15 is a planar schematic diagram of the touch layer, and FIG. 16 is a schematic diagram of a cross-section along the direction CC′ in FIG. 15. The touch layer 102 may include a first metal layer 10, an insulating layer 20, and a second metal layer 30 that are stacked. The first metal layer 10 includes bridging electrodes 101; and the second metal layer 30 includes: a plurality of first touch electrodes 301 arranged along a row direction X, a plurality of second touch electrodes 302 arranged along a column direction Y, and a connection electrode 303 between two adjacent first touch electrodes 301. The first touch electrodes 301 are electrically connected in pairs through a corresponding connection electrode 303, respectively; and each of the second touch electrodes 302 is electrically connected to a corresponding bridging electrode 101 through a via hole penetrating the insulating layer 20.

Optionally, the touch layer 102 may adopt a metal mesh architecture, i.e., the first touch electrodes 301 and the second touch electrodes 303 are located on the same film layer, and cooperate with a touch IC to realize the touch function.

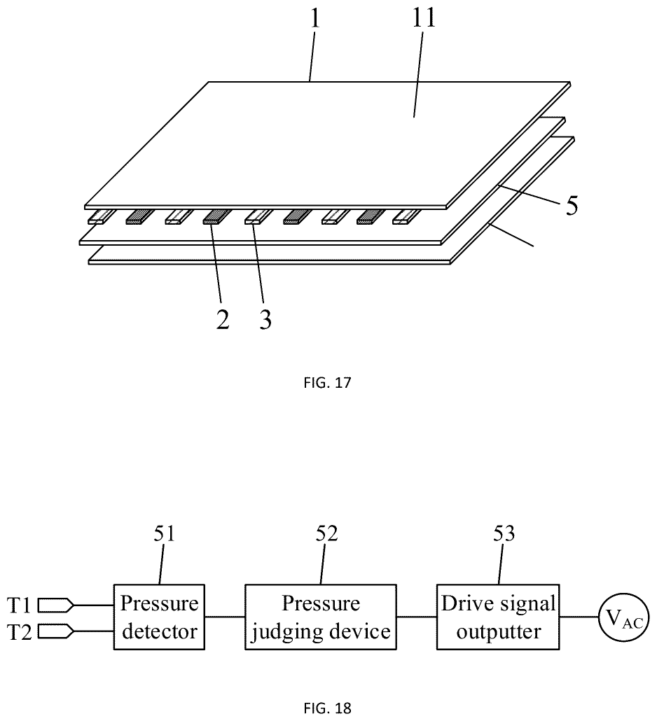

In specific implementation, the above haptic feedback panel provided by embodiments of the present disclosure, as shown in FIG. 17, further includes a circuit control board 5 disposed on one sides of the first piezoelectric device 2 and the second piezoelectric device 3 away from the touch substrate 1. As shown in FIG. 18, the circuit control board 5 includes a pressure detector 51, a pressure judging device 52, and a drive signal outputter 53. The pressure detector 51 is electrically connected to a pressure detection terminal (T1 and T2 in FIGS. 7-8), the pressure judging device 52 is electrically connected to the pressure detector 51, and the drive signal outputter 53 is electrically connected to the pressure judging device 52 and the drive signal terminal (VAC in FIGS. 9-10). For example, the threshold value of the trigger force of the haptic feedback panel is set to 100 g. The pressure detector 51 detects the voltage output by the first piezoelectric device, and when the pressure judging device 52 determines that the output voltage is greater than or equal to the voltage value generated by the pressing force of 100 g, the drive signal outputter 53 outputs an alternating current signal to the second piezoelectric device, so that the second piezoelectric device drives the touch substrate to generate resonance, realizing the vibration feedback function.

In specific implementation, the above haptic feedback panel provided in the embodiments of the present disclosure, as shown in FIG. 17, further includes a base shell 6 disposed on a side of the circuit control board 5 away from the touch substrate 1, and the base shell 6 is used to fix and protect the touch substrate 1.

In specific implementation, in the above-described haptic feedback panel provided by embodiments of the present disclosure, in addition to the various film layers mentioned above, other film layers may be provided according to actual applications.

The working principle of the haptic feedback panel provided in the embodiments of the present disclosure is described below.

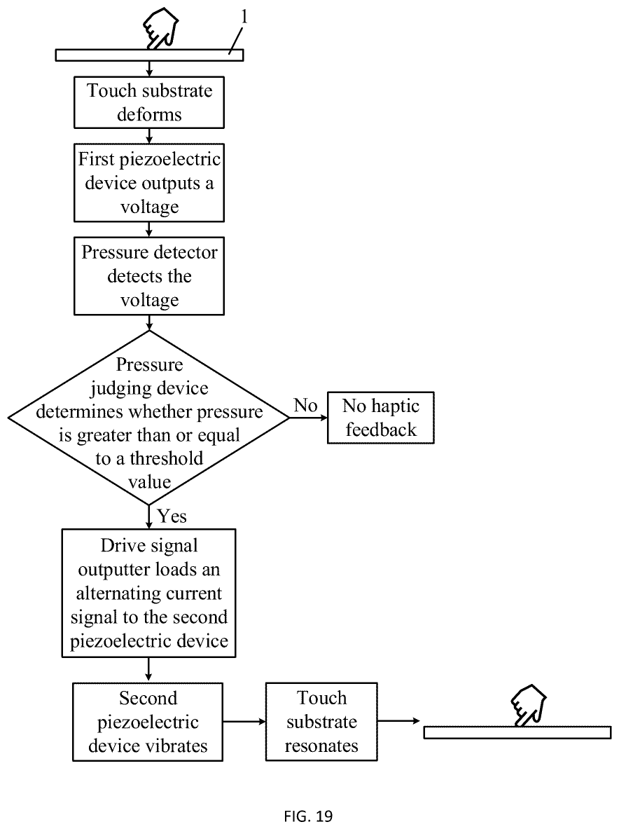

As shown in FIG. 19, the user (finger) presses the surface of the touch substrate 1, the touch substrate deforms and drives the first piezoelectric device to deform to generate a voltage, the first piezoelectric device outputs a voltage, the pressure detector detects the voltage, and the pressure judging device determines the magnitude of the pressing force corresponding to this voltage. It is assumed that when the trigger force reaches a certain threshold value (≥100 g), it is a finger clicking action on the touch substrate, and when the trigger force is less than 100 g, it is the finger sliding. If the pressure judging device determines that the pressing force corresponding to the voltage is less than 100 g, then the finger only slides on the touch substrate, there is only the slight pressing force, the voltage output by the first piezoelectric device is low, there is no need to load an alternating current signal to the second piezoelectric device, and the second piezoelectric device will be in the low-power mode without working, i.e., there is no haptic feedback. If the pressure judging device determines that the magnitude of the pressing force corresponding to the voltage is greater than or equal to 100 g, i.e., the finger clicks on the touch substrate, then the drive signal outputter loads an alternating current signal to the second piezoelectric device, the frequency of the alternating current signal is generally in the range of 100 Hz˜300 Hz, and the second piezoelectric device vibrates under the action of the alternating electric field and drives the touch substrate to resonate, realizing the haptic feedback. For example, the second piezoelectric device realizes electrical and mechanical energy conversion under the action of the alternating electric field, causing the entire touch substrate to generate the horizontal/vertical displacement and acceleration, and generating the tactile sensation similar to that of a mechanical button.

The touch substrate in the embodiments of the present disclosure can be a simple full-area touch panel in a laptop computer, and while retaining the touch function, the haptic feedback function is increased to enrich the user's real button touch feeling. At the same time, the touch substrate can also be a display screen, that is, the display integrated full-area touch substrate can be used as an external device, with the split-screen control panel function, additionally increasing the sub-screen function.

The application scenarios of the haptic feedback panel provided by embodiments of the present disclosure can specifically include the following two scenarios.

Scenario 1: the touch substrate is a simple full-area touch panel.
(1) When the finger slides on the display screen, an arrow of a mouse on the display screen can be controlled synchronously to realize the click/double-click function normally.
(2) When clicking/double-clicking the screen, the trigger force detection and vibration feedback function are realized, without depending on the coordinates of the touch layer; and it is a separate press-detect-trigger closed-loop circuit.

Scenario 2: the display integrated full-area touch substrate can be used as an external device, with the split-screen control panel function.
(1) When the laptop plays a video in a full screen, the display screen displays a separate control panel for volume adjustment, play/pause, stop, fast forward and fast rewind functions.
(2) When clicking the screen, the press-detect-trigger function is realized.

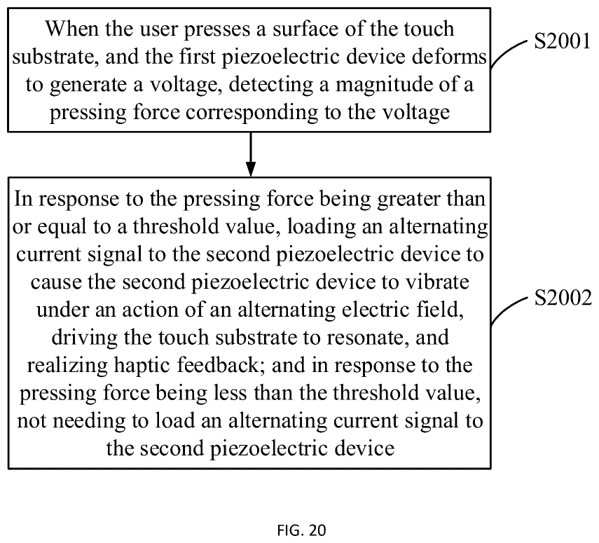

Based on the same inventive conception, embodiments of the present disclosure also provide a method for driving the above haptic feedback panel, as shown in FIG. 20, including:
S2001, when the user presses a surface of the touch substrate, and the first piezoelectric device deforms to generate a voltage, detecting a magnitude of a pressing force corresponding to the voltage; and
S2002, in response to the pressing force being greater than or equal to a threshold value, loading an alternating current signal to the second piezoelectric device to cause the second piezoelectric device to vibrate under an action of an alternating electric field, driving the touch substrate to resonate, and realizing haptic feedback; and in response to the pressing force being less than the threshold value, not needing to load an alternating current signal to the second piezoelectric device.

The driving principle and specific implementation of the driving method are the same as those of the haptic feedback panel in the above embodiments, and therefore, the driving method can be implemented by referring to the specific implementation of the haptic feedback panel in the above embodiments, which will not be repeated herein.

Based on the same inventive concept, embodiments of the present disclosure also provide a haptic feedback apparatus including the above-mentioned haptic feedback panel provided in the embodiments of the present disclosure. Since the principle of the haptic feedback apparatus for solving problems is similar to that of the haptic feedback panel described above, the implementation of the haptic feedback apparatus can refer to the implementation of the haptic feedback panel described above, and will not be repeated herein. The haptic feedback apparatus may be: a tablet computer, a television, a monitor, a laptop computer, a digital photo frame, a navigator, and any other product or component having a display or touch function.

In a haptic feedback panel and a driving method thereof, and a haptic feedback apparatus provided by the embodiments of the present disclosure, the single-layer first piezoelectric device is adopted to detect the pressure of a finger pressing onto the surface of the touch substrate. Compared to the multi-layer piezoelectric device, when pressing the single-layer piezoelectric device, the pressure per unit can generate a larger output voltage, which is conducive to improving the signal-to-noise ratio of the output voltage, facilitating the signal identification and processing of the circuit system, and improving the sensitivity of the pressure detection. The multi-layer second piezoelectric device is adopted to drive the overall resonance of the touch substrate, to generate vibration sensation, and realize haptic feedback. Since the second piezoelectric device includes at least three electrode layers that are stacked, then the second piezoelectric device includes at least two second piezoelectric layers, and thus it is equivalent to the second piezoelectric device including at least two piezoelectric structures arranged in parallel. The overall driving voltage of the second piezoelectric device is equal to the single-layer driving voltage, and the haptic feedback strengths of the second piezoelectric layers in the parallel structure can be superimposed. Therefore, compared to the related art in which a thicker piezoelectric layer needs to be set in order to improve the haptic feedback strength, which leads to the problem of a high driving voltage loaded in the related art, in the embodiments of the present disclosure, by setting the sum of the thicknesses of the second piezoelectric layers equal to the thickness of a whole layer in the related art, a haptic feedback strength same as that in the related art can be achieved. For example, the three second piezoelectric layers are provided, so that the driving voltage corresponding to each second piezoelectric layer can be reduced to one-third of that in the related art. Therefore, the haptic feedback panel provided in embodiments of the present disclosure adopts the single-layer first piezoelectric device to improve the sensitivity of pressure detection, and adopts the multi-layer second piezoelectric device to realize vibration feedback driven by a low voltage.

Although preferred embodiments of the present disclosure have been described, those skilled in the art may make additional changes and modifications to these embodiments once the basic inventive concepts are known. Therefore, the appended claims are intended to be construed to include the preferred embodiments as well as all changes and modifications that fall within the scope of the present disclosure.

Obviously, a person skilled in the art can make various modifications and variations to the embodiments of the present disclosure without departing from the spirit and scope of the embodiments of the present disclosure. Thus, if such modifications and variations of the embodiments of the present disclosure fall within the scope of the claims of the present disclosure and their technical equivalents, the present disclosure is intended to include such modifications and variations.

1-27. (canceled)

28. A haptic feedback panel, comprising:
a touch substrate;
at least one first piezoelectric device on the touch substrate; wherein the first piezoelectric device comprises a single first piezoelectric layer, and the first piezoelectric device is configured to detect pressure pressed onto a surface of the touch substrate; and
at least one second piezoelectric device on the touch substrate; wherein the second piezoelectric device comprises at least three electrode layers that are stacked, and a second piezoelectric layer between every two adjacent electrode layers; and the second piezoelectric device is configured to vibrate under an action of an alternating electric field and to drive the touch substrate to resonate.

29. The haptic feedback panel according to claim 28, wherein the first piezoelectric device and the second piezoelectric device are both disposed on a non-touch surface of the touch substrate; and
an orthographic projection of the first piezoelectric device on the touch substrate and an orthographic projection of the second piezoelectric device on the touch substrate do not overlap.

30. The haptic feedback panel according to claim 29, wherein a plurality of first piezoelectric devices are provided, a plurality of second piezoelectric devices are provided, the plurality of first piezoelectric devices are arranged in an array on the non-touch surface of the touch substrate, the plurality of second piezoelectric devices are arranged in an array on the non-touch surface of the touch substrate, and columns of the first piezoelectric devices and columns of the second piezoelectric devices are alternately arranged.

31. The haptic feedback panel according to claim 28, wherein the first piezoelectric device comprises a first electrode, the first piezoelectric layer, and a second electrode that are stacked; and the first electrode is in contact with the non-touch surface of the touch substrate;
the first piezoelectric layer has a first surface in contact with the second electrode, and the first electrode has a first end extending along a side edge of the first piezoelectric layer to the first surface; wherein,
the first end is electrically connected to a first voltage detection terminal, and the second electrode is electrically connected to a second voltage detection terminal.

32. The haptic feedback panel according to claim 31, wherein in all of the first piezoelectric devices, first ends of all first electrodes are electrically connected to the first voltage detection terminals, and all second electrodes are electrically connected to the second voltage detection terminals.

33. The haptic feedback panel according to claim 31, wherein in a same row of the first piezoelectric devices, first ends of all first electrodes are electrically connected to a same first voltage detection terminal, and all second electrodes are electrically connected to a same second voltage detection terminal; and
in different rows of the first piezoelectric devices, first ends of the first electrodes are electrically connected to different first voltage detection terminals, and the second electrodes are electrically connected to different second voltage detection terminals.

34. The haptic feedback panel according to claim 32, wherein the first end of the first electrode is electrically connected to the first voltage detection terminal via a first lead, and the second electrode is electrically connected to the second voltage detection terminal via a second lead; and
both the first lead and the second lead comprise a conductive wire and an insulating film wrapping the conductive wire.

35. The haptic feedback panel according to claim 28, wherein in one second piezoelectric device, for all of the electrode layers, odd-numbered electrode layers are electrically connected to each other, even-numbered electrode layers are electrically connected to each other, and the odd-numbered electrode layers and the even-numbered electrode layers are insulated from each other.

36. The haptic feedback panel according to claim 35, wherein the second piezoelectric device further comprises a first conductive portion and a second conductive portion extending in a thickness direction of the haptic feedback panel, and the first conductive portion and the second conductive portion are disposed on two opposite sides of the second piezoelectric layer; wherein,
the odd-numbered electrode layers are electrically connected through the first conductive portion, and the even-numbered electrode layers are electrically connected through the second conductive portion.

37. The haptic feedback panel according to claim 36, wherein the first conductive portion has a second end extending to a bottom surface of a bottom second piezoelectric layer that is closest to the non-touch surface, and the second conductive portion has a third end extending to a top surface of a top second piezoelectric layer that is farthest away from the non-touch surface; wherein
the third end is electrically connected to a ground terminal, and the electrode layer of the odd-numbered electrode layers farthest away from the non-touch surface is electrically connected to a drive signal terminal.

38. The haptic feedback panel according to claim 37, wherein in all of the second piezoelectric devices, third ends of all second conductive portions are electrically connected to a same ground terminal, and the electrode layers in the odd-numbered electrode layers that are farthest away from the non-touch surface are electrically connected to a same drive signal terminal.

39. The haptic feedback panel according to claim 37, wherein in all of the second piezoelectric devices, third ends of all second conductive portions are electrically connected to a same ground terminal;
in the same row of the second piezoelectric devices, the electrode layers of the odd-numbered electrode layers that are farthest away from the non-touch surface are all electrically connected to a same drive signal terminal; and
in different rows of the second piezoelectric devices, the electrode layers of the odd-numbered electrode layers that are farthest away from the non-touch surface are electrically connected to different drive signal terminals.

40. The haptic feedback panel according to claim 38, wherein a third end of the second conductive portion is electrically connected to the ground terminal via a third lead, and the electrode layer of the odd-numbered electrode layers that is farthest away from the non-touch surface is electrically connected to the drive signal terminal via a fourth lead; and
both the third lead and the fourth lead comprise a conductive wire and an insulating film wrapping the conductive wire.

41. The haptic feedback panel according to claim 28, wherein a spacing between two adjacent columns of the first piezoelectric devices ranges from 20 mm to 30 mm, and a spacing between two adjacent first piezoelectric devices in a same column ranges from 20 mm to 30 mm; and
a spacing between two adjacent columns of the second piezoelectric devices ranges from 20 mm to 30 mm, and a spacing between two adjacent second piezoelectric devices in a same column ranges from 20 mm to 30 mm.

42. The haptic feedback panel according to claim 28, wherein an area of the first piezoelectric device ranges from 50 mm² to 150mm², and a shape of the first piezoelectric device comprises a rectangle, a square or a circle; and
an area of the second piezoelectric device ranges from 50 mm₂ to 150mm₂, and a shape of the second piezoelectric device comprises a rectangle, a square or a circle.

43. The haptic feedback panel according to claim 28, wherein a thickness of the first piezoelectric layer is the same as a total thickness of the second piezoelectric layers;
wherein the thickness of the first piezoelectric layer ranges from 0.3 mm to 0.6 mm and the total thickness of the second piezoelectric layers ranges from 0.3 mm to 0.6 mm;
wherein a thickness of each of the second piezoelectric layers is substantially the same, and the thickness of each of the second piezoelectric layers is less than or equal to 100 μm;
wherein the thickness of each of the second piezoelectric layers ranges from 10 μm to 30 μm;
wherein a layer number of the second piezoelectric layers ranges from 2 to 20;
wherein materials of the electrode layer comprise silver, silver palladium, platinum, and gold.

44. The haptic feedback panel according to claim 28, wherein the touch substrate comprises a display substrate and a touch layer on a side of a display surface of the display substrate, and
the first piezoelectric device and the second piezoelectric device are both disposed on a non-display surface of the display substrate;
wherein the touch layer comprises a first metal layer, an insulating layer, and a second metal layer that are stacked;
the first metal layer comprises bridging electrodes;
the second metal layer comprises: a plurality of first touch electrodes arranged in a row direction, a plurality of second touch electrodes arranged in a column direction, and a connection electrode between two adjacent first touch electrodes;
the plurality of first touch electrodes are electrically connected in pairs through a corresponding connection electrode, respectively; and
each of the plurality of second touch electrodes is electrically connected to a corresponding bridging electrode through a via hole penetrating the insulating layer.

45. The haptic feedback panel according to claim 28, further comprising a circuit control board on one sides of the first piezoelectric device and the second piezoelectric device away from the touch substrate;
the circuit control board comprises a pressure detector, a pressure judging device, and a drive signal outputter;
the pressure detector is electrically connected to a pressure detection terminal;
the pressure judging device is electrically connected to the pressure detector; and
the drive signal outputter is electrically connected to the pressure judging device and the drive signal terminal;
wherein the haptic feedback panel further comprises a base shell on a side of the circuit control board away from the touch substrate.

46. A haptic feedback apparatus, comprising a haptic feedback panel comprising:
a touch substrate;
at least one first piezoelectric device on the touch substrate; wherein the first piezoelectric device comprises a single first piezoelectric layer, and the first piezoelectric device is configured to detect pressure pressed onto a surface of the touch substrate; and
at least one second piezoelectric device on the touch substrate; wherein the second piezoelectric device comprises at least three electrode layers that are stacked, and a second piezoelectric layer between every two adjacent electrode layers; and the second piezoelectric device is configured to vibrate under an action of an alternating electric field and to drive the touch substrate to resonate.

47. A method for driving the haptic feedback panel according to claim 28, comprising:
when a user presses the surface of the touch substrate and the first piezoelectric device deforms to generate a voltage, detecting a magnitude of a pressing force corresponding to the voltage;
in response to the pressing force being greater than or equal to a threshold value, loading an alternating current signal to the second piezoelectric device to cause the second piezoelectric device to vibrate under the action of the alternating electric field, driving the touch substrate to resonate, and realizing haptic feedback; and
in response to the pressing force being less than the threshold value, not needing to load the alternating current signal to the second piezoelectric device.
